(19) United States
(12) Patent Application Publication
(10) Pub. No.: US 2005/0068832 A1
(43) Pub. Date: Mar. 31, 2005

(54) Semiconductor storage device

(75) Inventor: Takeshi Andoh, Kanagawa (JP)

Correspondence Address: MCGINN & GIBB, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 10/938,635

(22) Filed: Sep. 13, 2004

(30) Foreign Application Priority Data
Sep. 29, 2003 (JP) 2003-338890

(51) Int. Cl. G11C 7/00

(52) U.S. Cl. 365/222

(57) ABSTRACT

A semiconductor storage device detects a temperature T0 at which an output voltage Vtemp of the temperature detecting circuit equals to an output voltage Vref0 of the reference voltage generating circuit. In the lower temperature range lower than the temperature T0, the value of the reference voltage Vref is reduced by a preset voltage ΔV from an external power supply voltage Vdd by a variable voltage generating circuit. The lowered voltage (Vdd−ΔV) is applied to the word line WL of the memory cell via the word line driver as a variable power supply voltage Vcp.

### FIELD OF THE INVENTION

The present invention relates to a semiconductor storage device and in particular to a semiconductor storage device consisting of an SRAM (Static Random Access Memory) having a plurality of four-transistor cells, each comprising a pair of access transistors and a pair of driver transistors.

### BACKGROUND OF THE INVENTION

The semiconductor storage devices (semiconductor memories) are mainly classified into volatile memories and non-volatile memories. The volatile memories are further classified into SRAMs and DRAMs (Dynamic Random Access Memories). Most of these semiconductor memories comprise MOS (Metal Oxide Semiconductor) transistors which are excellent in integration density. SRAMs have advantages that they are adapted to high-speed operation and do not require any refreshing operation which is essential to DRAMs, and hence they are used in a wide range of applications in the field of memory of medium storage capacity. Since SRAMs can be manufactured in a process which is basically compatible with that of logic LSIs, a number of SRAMs are also used as embedded memories in system LSIs.

Presently, most typical SRAM has 6-transistor cells, each comprising 6 MOS transistors. As shown in FIG. 9, the SRAM has a 6-transistor cells, each comprising a pair of nMOS transistors MA10 and MA20 constituting a pair of access transistors; a pair of nMOS (n-channel MOS) transistors MD10 and MD20 constituting a pair of driver transistors; and a pair of pMOS (p-channel MOS) transistors ML10 and ML20 constituting a pair of load transistors. The pMOS transistor ML10 and the nMOS transistor MD10 are connected in series across a power supply Vdd and the ground GND to constitute a CMOS (complementary MOS) inverter and the pMOS transistor ML20 and the nMOS transistor MD20 are connected in series across the power supply Vdd and the ground GND to constitute a CMOS inverter. An input of each CMOS inverter is cross-connected to an output of the other CMOS inverter to constitute a flip-flop circuit. Respective cross-connecting nodes form storage nodes P10 and P20. The nMOS transistors MA10 and MA20 have their gates connected in common to a word line WL, have their sources connected to bit (digit) lines DT and DB, respectively, and have drains connected to storage nodes P10 and P20, respectively. An SRAM is formed by arraying a plurality of above-mentioned cells in a matrix arrangement.

The semiconductor chip size of the above-mentioned SRAM, in which each cell is composed of 6-transistors, is large. This becomes an obstacle for an integration of the SRAM on a semiconductor substrate. There has been proposed a 4-transistor cell, each comprising a pair of access transistors and a pair of driver transistors in which a pair of load transistors are omitted from the circuit configuration shown in FIG. 9 to eliminate the above-mentioned drawback. Such a 4-transistor cell is so adapted that the pair of the access transistors also serves as the pair of load transistors. The pair of access transistors are turned off by setting the word line WL and digit (bit) lines DT and DB to a high level when data on each storage node is to be held. The off current (off leakage current) enables the high level of the storage node to be held.

The SRAM having the above-mentioned 4-transistor cells is disclosed in, for example patent reference 1. FIG. 10 is a diagram showing the configuration of a semiconductor storage (SRAM) device disclosed in the patent reference 1. Referring to FIG. 10, the SRAM device comprises a word line driver 21, a memory cell 22, a variable voltage generating circuit 23. Each memory cell 22 comprises a pair of pMOS transistors Mt1 and Mt2 constituting a pair of load and access transistors (transfer transistors) and a pair of nMOS transistors Md1 and Md2 constituting a pair of driver transistors. A connection node between the transistor Mt1 and the transistor Md1 forms a storage node P1 and a connection node between the transistor Mt2 and the transistor Md2 forms another storage node P2.

The word line driver 21 comprises an nMOS transistor Mn3 and a pMOS transistor Mp6 which are connected in series to compose a CMOS inverter. The transistors Mn3 and Mp6 have their gates connected in common to an input and have their drains connected in common to the word line WL as outputs. The transistor Mn3 has its source connected to the ground GND and the transistor Mp6 has its source connected to a variable voltage VR1. High and low levels of the word line WL are VR1 and GND (ground potential), respectively.

The VR generating circuit 23 comprises a reference voltage generating circuit 27, and an operational amplifier OP. The operational amplifier OP (configured as a voltage follower) receives at an non-inverting input thereof a reference voltage Vref1 output from the reference voltage generating circuit 27 and outputs the reference voltage Vref1 to the word line WL as a variable voltage VR1. Illustration of the internal structure of the reference voltage generating circuit 27 is omitted herein. There is disclosed in FIG. 3 of the Patent reference 1, the circuit configuration of the reference voltage generating circuit 27, which comprises a series circuit of a pMOS transistor Mp10 having the same characteristics as those of the access transistor of the memory cell and an nMOS transistor Mn7 having the same characteristics as those of the driver transistor, in which the transistor Mn7 has its gate and source connected to the GND and its drain connected to Vref1 and the transistor Mp10 has its gate and drain connected to Vref1 and its source connected to an power supply (Vcc).

During a data holding period in the memory cell 22, the word line WL is set to a high level (VR1 level) to turn off the pMOS transistors Mt1 and Mt2 constituting access transistors and digit (bit) lines D and DB are connected to the power supply Vcc so that the high level on the storage node is held by off currents of the access transistors.

In order to stably keep the high level on the storage node P2 during a data holding period, it is only required that the off current of the pMOS transistor Mt2 is larger than the off current of the nMOS transistor Md2. The off current for keeping the same potential of the storage node P2 in the memory cell which is in a state of holding data, flows into the reference voltage generating circuit 27, so that the reference voltage generating circuit 27 outputs its potential as the reference voltage Vref1. The influence of variations in manufacturing processes of SRAMs having such cells similarly occur in both memory cell 22 and reference voltage generating circuit 27 and hence the variable voltage VR1 can be adjusted so that the off resistance of the access transistor becomes optimum.

[Patent Reference]

1. Japanese Patent Kokai Publication No. JP-P2000-260186A

### SUMMARY OF THE DISCLOSURE

The above-mentioned conventional semiconductor storage device has a problem that data retention failure may occur, during a data holding period of the memory cell, in particular, when the device is operated at a low temperature.

In the memory cell 22 of the SRAM, shown in FIG. 10, during a data holding period, as mentioned above, the word line WL and digit lines D and DB are precharged to a high level and the high level on the storage node is held by the off current of the pMOS transistors Mt and Mt2 constituting access transistors. The potential of the high level is divided by the off resistance Roffp of pMOS transistors Mt1 and Mt2 and the off resistance Roffn of the nMOS transistors Md1 and Md2 constituting driver transistors, the condition for holding the high level is represented as follows:
(Roffp/Roffn)<1

That is, this condition can be formulated by a relationship between the off current Ioffp of pMOS transistors Mt1 and Mt2 constituting access transistors and the off current Ioffn of the nMOS transistors Md1 and Md2 constituting driver transistors as follows:
(Ioffp/Ioffn)>1
(Ioffp/Ioffn) is hereinafter referred to as “Ioff ratio”.

The above-mentioned off currents Ioffp and Ioffn depend upon a subthreshold leakage. The threshold voltages of the pMOS transistors Mt1 and Mt2 constituting access transistors and the nMOS transistors Md1 and Md2 constituting drive transistors are represented as Vthp and Vthn, respectively. The above-mentioned requirement (Ioffp/Ioffn)>1 is achieved by setting the relation |Vthp¦<Vthn. Since there is a positive correlation between the off current and on current, the ratio of the on current Ionn of the nMOS transistors Md1 and Md2 to the on current Ionp of the pMOS transistors Mt1 and Mt2 (Ionn/Ionp) decreases as the above-mentioned Ioff ratio increases. This reduces static noise margin and may incur readout failure, so that the preset range of the above-mentioned Vthp and Vthn is limited. An increase in Ioffp directly increases stand-by current of the memory cell, so that precaution is also necessary.

The temperature dependency of the off current Ioff, as shown in FIG. 11 is derived from the above-mentioned relationship ¦Vthp¦<Vthn. As is apparent from the drawing, the off current Ioffp is larger than the off current Ioffn and the difference between them increases as the temperature is lowered. The above-mentioned Ioff ratio becomes larger as the temperature is lowered and hence the memory cell has more excellent data holding characteristics at lower temperatures. The Ioff ratio is assured as large as three digits at the room ambient temperature in view of the influence upon the manufacturing variations of the semiconductor storage devices. FIG. 11 shows the casein which the Ioff ratio is decreased to single digit (for example, Ioffp is decreased by one digit and Ioffn is increased by one digit). Furthermore, unexpected leakage currents such as junction leakage current and contact leakage currents may occur between the drain of the nMOS transistors Md1 and Md2 constituting driver transistors and the GND. The temperature dependency of such an off current is shown in, for example, FIG. 12. As is apparent from the drawing, such a leakage current appears as an increase in Ioffn, so that the relation (Ioffp>Ioffn)>1 may not be satisfied at a lower temperature range at which subthreshold leakage is low. In the example of FIG. 12, (Ioffp/Ioffn)<1, at temperatures of −20° C. or less. The fact that the relationship of (Ioffp/Ioffn)>1 is not satisfied at lower temperatures means that data retention failure is liable to occur particularly at lower temperatures. Since such failures may occur in minority bits, it is impossible for the SRAM disclosed in Patent Reference 1 which detects a change in characteristics in majority bits to avoid the above-mentioned data retention failure.

Accordingly, it is an object of the present invention to provide a semiconductor storage device, which is capable of avoiding data retention failure which is liable to occur particularly at lower temperatures during a data-holding period of a memory cell.

The above and other objects are attained by a semiconductor storage device, in accordance with one aspect of the present invention, which includes: a plurality of four-transistor memory cells, each of said memory cells including: a pair of access transistors controlled in common by a word line; and a pair of driver transistors each connected in series with associated one of said pair of access transistors, respectively; respective connection nodes between said access transistors and said driver transistors constituting storage nodes, on which given voltage levels are held by off currents of said access transistors, during a data holding period; and means for performing control so as to increase said off currents of said access transistors, during the data holding period, in a relatively low temperature region.

A semiconductor storage device, according to another aspect of the present invention, includes: a plurality of four-transistor memory cells, each of said memory cells including: a pair of access transistors controlled in common by a word line; and a pair of driver transistors, each connected in series with associated one of said pair of access transistors, respectively; respective connection nodes between said access transistors and said driver transistors constituting storage nodes, on which given voltage levels are held by off currents of said access transistors, during a data holding period;
a temperature detecting circuit for outputting a detected voltage dependent on operation temperature of said memory cells;
a reference voltage generating circuit for outputting a reference voltage independent of the operation temperature of said memory cells;
a first differential amplifier for comparing said detected voltage with said reference voltage to output a voltage of a first or second level in accordance with a result of said comparison;
a variable voltage generating circuit, receiving as two inputs a branch of the output of said first differential amplifier, for outputting an output signal, the potential of which is varied in accordance with said first and second levels of the output of said first differential amplifier; and
a word line driver, receiving the output from the variable voltage generating circuit, for supplying said word line with the output voltage of said variable voltage generating circuit.

The semiconductor storage device, according to still another aspect of the present invention, includes the variable voltage generating circuit which comprises a reference voltage generating unit which receives one of said branched outputs of said first differential amplifier; an output unit which receives the other one of said branched outputs of said second differential amplifier; and a second differential amplifier which receives the outputs of said reference voltage generating unit and said output unit.

The semiconductor storage device, according to the present invention, may preferably be so adapted that when said reference voltage is higher than said detected voltage, said first differential amplifier outputs the first level voltage and control is performed in response to the output of said first differential amplifier so as to make both said reference voltage generating unit and said second differential amplifier stop respective operations and to make said variable voltage generating circuit output a voltage which is equal to that of an external power supply.

The semiconductor storage device, according to the present invention, may preferably be so adapted that when said reference voltage is lower than said detected voltage, said first differential amplifier outputs said second level voltage and both said reference voltage generating unit and said second differential amplifier responsively start their operation and said variable voltage generating circuit outputs a voltage which is lowered by a preset desired value from that of an external power supply.

In the semiconductor storage device, according to the present invention, said reference voltage generating unit preferably comprises a series circuit of two transistors, and in that said desired value is preset by changing the dimension of each transistor of said series circuit.

In the semiconductor storage device, according to the present invention, said first and second levels are low (L) and high (H) levels, respectively.

In the semiconductor storage device, according to the present invention, said one pair of access transistors comprise pMOS transistors; and said one pair of driver transistors comprises nMOS transistors.

In the semiconductor storage device, according to the present invention, said temperature detecting circuit has a temperature detecting element.

In the semiconductor storage device, according to the present invention, said temperature detecting element has a diode.

In the semiconductor storage device, according to the present invention, detection of said temperature is conducted based upon the forward voltage of said diode.

The meritorious effects of the present invention are summarized as follows.

With the semiconductor storage device according to the present invention, the value of the reference voltage is reduced by a preset desired voltage from the external power supply voltage, particularly in a lower temperature range, during a data holding period of a memory cell and the lowered voltage is supplied to the word line of the memory cell via a word line driver as a variable voltage power supply, as a result of which, data retention failure, which is liable to occur particularly in the lower temperature range, during the data holding period, can be prevented.

Still other objects and advantages of the present invention will become readily apparent to those skilled in this art from the following detailed description in conjunction with the accompanying drawings wherein only the preferred embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1 is a diagram showing the configuration of a semiconductor storage device according to an embodiment of the present invention;

FIG. 2 is a diagram showing the configuration of a temperature detecting circuit of the semiconductor storage device according to an embodiment of the present invention;

FIG. 3 is a diagram showing the configuration of a word line driver of the semiconductor storage device according to an embodiment of the present invention;

FIG. 4 is a diagram showing the configuration of a memory cell of the semiconductor storage device according to an embodiment of the present invention;

FIG. 5 is a graph showing the temperature dependency of the output voltage of the temperature detecting circuit of the semiconductor storage device according to an embodiment of the present invention;

FIG. 6 is a graph showing the temperature dependency of a variable voltage power supply of the semiconductor storage device according to an embodiment of the present invention;

FIG. 7 is a graph showing the temperature dependency of the off currents of the access and driver transistors.

FIG. 8 is a diagram showing the configuration of the output unit of the variable voltage generating circuit of a semiconductor storage device according to a second embodiment of the present invention;

FIG. 9 is a diagram showing the configuration of six-transistor memory cell of a prior art semiconductor storage device;

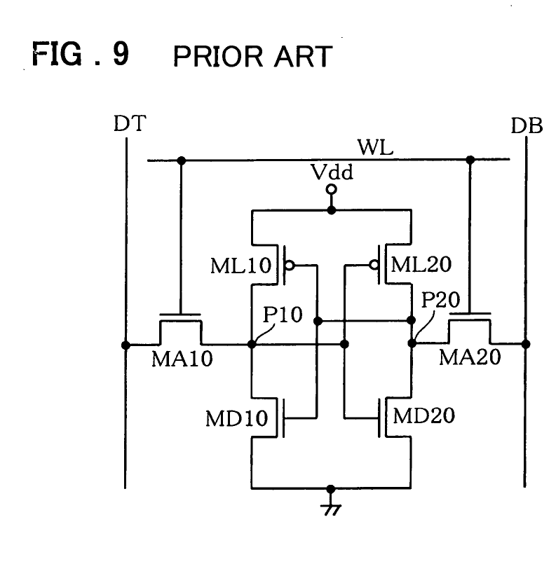

FIG. 10 is a diagram showing the configuration of a prior art semiconductor storage device;

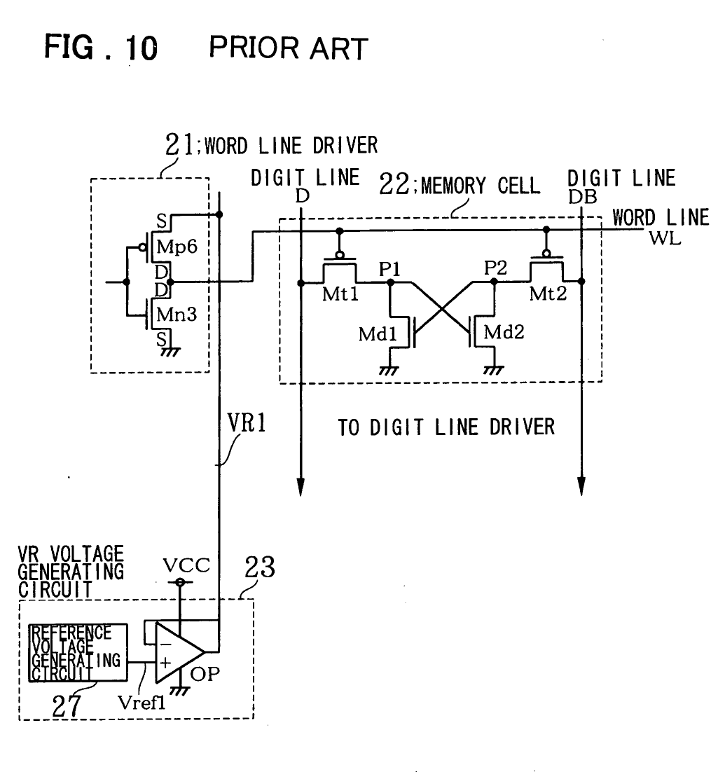

FIG. 11 is a graph showing the temperature dependency of off currents of access and driver transistors of a prior art semiconductor storage device; and

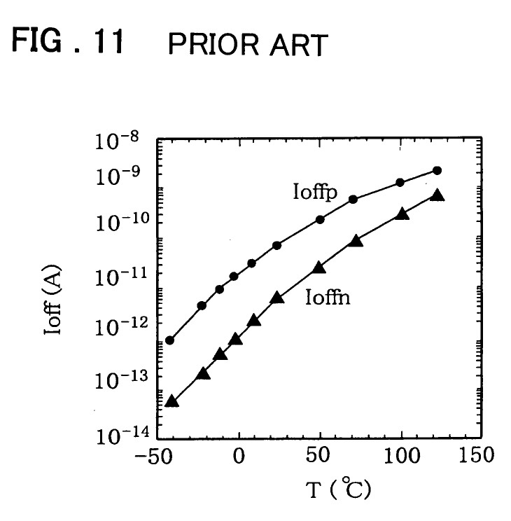

FIG. 12 is a graph showing the temperature dependency of off currents of access and driver transistors of a prior art semiconductor storage device.

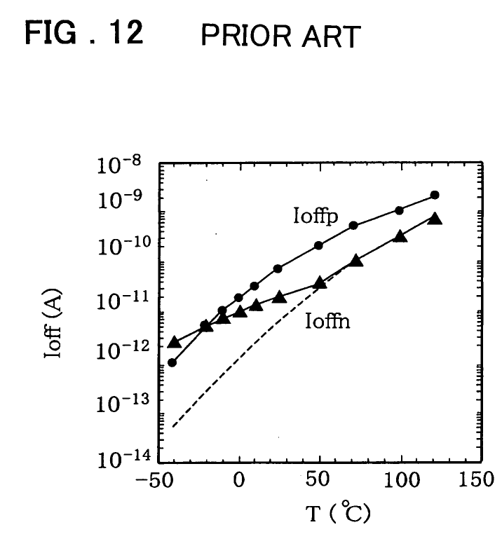

### PREFERRED EMBODIMENTS OF THE INVENTION

Preferred embodiments of the present invention will be described in the below. In the semiconductor storage device according to the present invention, the temperature T0 at which an output voltage Vtemp of a temperature detecting circuit equals to an output voltage Vref0 of a reference voltage generating circuit is detected. In the lower temperature range, which is not higher than the temperature T0, the value of the reference voltage Vref is lowered by a desired voltage ΔV from an external power supply voltage Vdd and the lowered voltage (Vdd−ΔV) is applied to the word line WL of the memory cell via the word line driver as a variable power supply voltage Vcp.

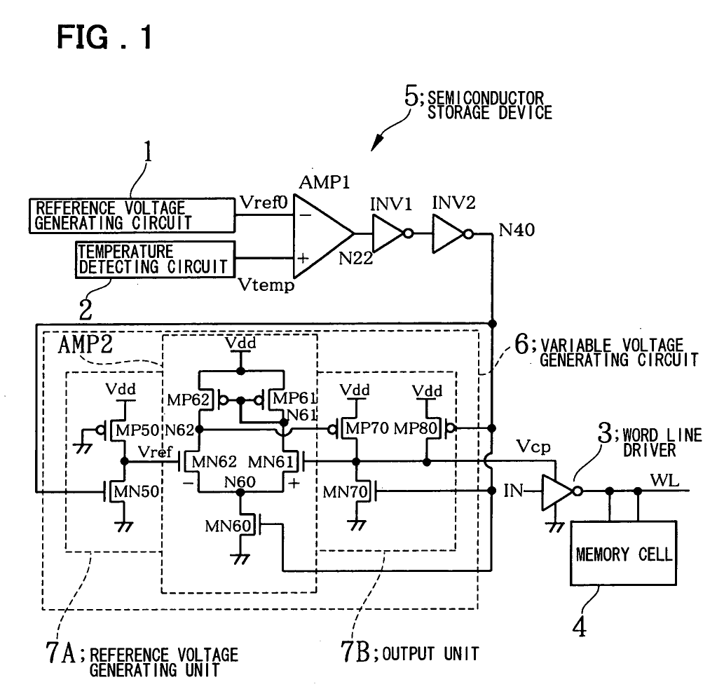

With reference to FIG. 1 through FIG. 7, a first embodiment of the present invention will be described.

Referring to FIG. 1, the semiconductor storage device 5 according to the present embodiment, comprises a temperature detecting circuit 2; a reference voltage generating circuit 1; a first differential amplifier AMP1 having anon-inverting input for receiving an output voltage Vtemp from the temperature detecting circuit 2 and an inverting input for receiving an output voltage Vref0 from the reference voltage generating circuit 1; a first and second inverters 1NV1 and 1NV2 which are connected in series between an output node N22 of the first differential amplifier AMP1 and a node N40; a variable voltage generating circuit 6 having inputs connected to two paths branched from the node N40, respectively; a word line driver 3 receives an output Vcp of the variable voltage generating circuit 6 as a power supply; and a memory cell 4 which is connected to a word line WL that is an output of the word line driver 3.

The variable voltage generating circuit 6 comprises a reference voltage generating circuit 7A, an output unit 7B and a second differential amplifier AMP2.

The reference voltage generating circuit 7A includes a pMOS transistor MP50 and an nMOS transistor MN50 connected in series between the power supply Vdd and the ground GND. More specifically, the pMOS transistor MP50 has its source, gate and drain connected to the power supply Vdd, the GND and the drain of the nMOS transistor MN50 respectively, and the nMOS transistor MN50 has its gate and source connected to one of branched paths of the node N40 and the GND respectively.

The output unit 7B includes a pMOS transistor MP80, a pMOS transistor MP70 and an nMOS transistor MN70. More specifically, the pMOS transistor MP80 has its drain, gate and source connected to the power supply Vdd, the other branched path of the node N40 and a variable voltage power supply Vcp of the word line driver 3, respectively, the pMOS transistor MP70 has its source, gate and drain connected to the power supply Vdd, an output node (N62) of the second differential amplifier AMP2, and the drain of the nMOS transistor MN70 respectively, and the nMOS transistor MN70 has its gate and source connected to the other branched path of the node N40 and the GND respectively. The node at which the drains of the pMOS transistors MP70 and MP80 and the drain of nMOS transistor MN70 are tied together is an output of the output unit 7B and is also connected to the variable voltage power supply Vcp of the word line driver 3.

In the output unit 7B, pMOS transistors MP70 and MP80 serve to supply currents. The pMOS transistor MP80 and the nMOS transistor MN70 are complementarily on/off controlled by the logic level of the node N40 to execute charging and discharging of the output node of the output unit 7B respectively, while the pMOS transistor MP70 receiving the output of the second differential amplifier AMP2, executes charging of the output node of the output unit 7B when it is turned on.

The second differential amplifier AMP2 has one input for receiving a reference voltage Vref, which is an output of the reference voltage generating unit 7A and the other input for receiving an output of the output unit 7B.

Referring to FIG. 1, the second differential amplifier AMP 2 comprises a pair of sources coupled nMOS transistors MN61 and MN62 constituting a differential pair, an nMOS transistor MN60 constituting a current source for supplying a current to the differential pair and a pair of pMOS transistors MP61 and MP62 constituting a current mirror for serving as an active load to the differential pair.

More specifically, the reference voltage Vref is connected to the gate of the nMOS transistor MN62. The source and drain of the transistor MN62 are connected to nodes N60 and N62, respectively. The gate, source and drain of the nMOS transistor MN61 are connected to the variable voltage power supply Vcp of the word line driver 3, the nodes N60 and N62, respectively, the source, drain and gate of the nMOS transistor MN60 are connected to the GND, the nodes N60 and the node N40, respectively.

In the second differential amplifier AMP 2, the pMOS transistor MP61 has its gate and drain connected in common to the node N61 and its source connected to the power supply Vdd, respectively. The pMOS transistor MP62 has its gate, source and drain connected to the node N61, the Vdd and node N62, respectively. The node N62 is an output of the second differential amplifier AMP2 and is connected to the gate of the pMOS transistor MP70 of the output unit 7B. The source and drain of the pMOS transistor MP70 is connected to the Vdd and the variable voltage power supply Vcp, respectively and connected to the other input (inverting input terminal) to form a feedback loop. That is, the second differential amplifier AMP2 is configured as a voltage-follower.

The other branched path of the node N40 is connected in common to the gates of the transistors MN60, MN70 and MP80.

Although a plurality of word line drivers 3 are connected to the variable voltage power supply Vcp, only one word line driver 3 is illustrated. Although a plurality of memory cells 4 are connected to the output of the word line driver 3 via the word lines WL, only one memory cell 4 is illustrated.

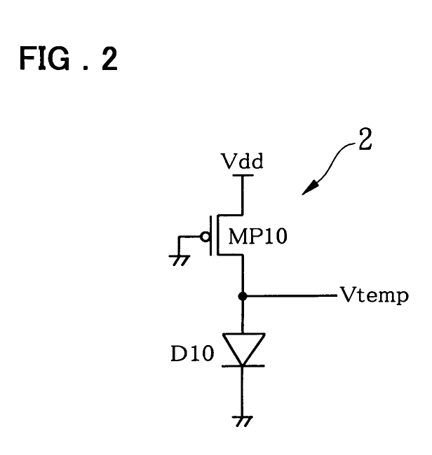

Referring to FIG. 2, the temperature detecting circuit 2 comprises a pMOS transistor MP10 and diode D10 connected in series between the power supply Vdd and the GND. The pMOS transistor MP10 has its drain connected to the anode of the diode D10 which has its cathode connected to the GND, so that the potential of the connection node between them is an output voltage Vtemp. The transistor MP10 has its gate and source connected to the GND and the power supply Vdd, respectively.

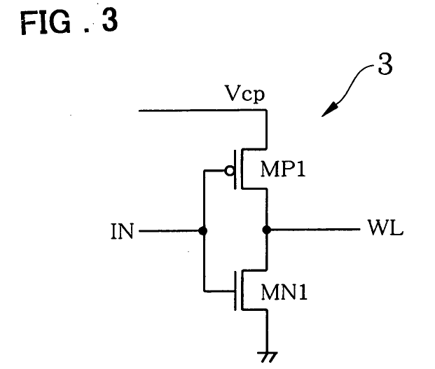

Referring to FIG. 3, the word line driver 3, includes a pMOS transistor MP1 and an nMOS transistor MN1 connected in series to form a CMOS inverter. More specifically, the pMOS transistors MP1 has its source, gate and drain connected to the variable voltage power supply Vcp of the word line driver 3, a word line control signal IN, and a word line WL, respectively and the nMOS transistors MN1 has its source, gate and drain connected to the GND, the word line control signal IN, and the word line WL, respectively.

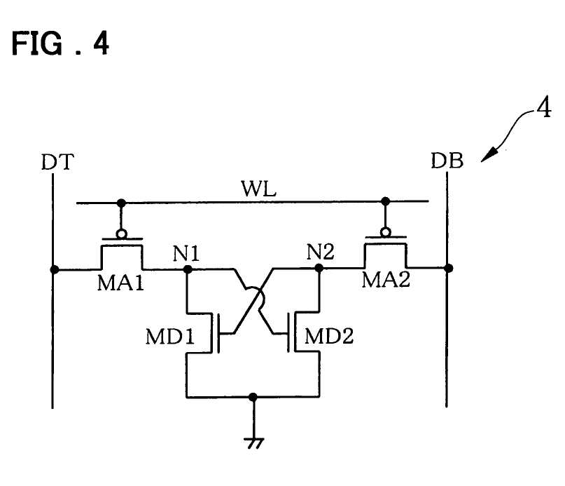

Referring to FIG. 4, the memory cell 4, according to the present embodiment, comprises four transistors, such as a pair of pMOS transistors MA1 and MA2 constituting a pair of both load and access transistors; and a pair of nMOS transistors MD1 and MD2 constituting a pair of driver transistors. Storage nodes N1 and N2 are formed between transistors MA1 and MD1 and between the transistors MA2 and MD2, respectively. The gates of the transistors MA1 and MA2 are connected to the word line WL. The sources of the transistors MA1 and MA2 are connected to digit (bit) lines DT and DB, respectively. The drains of the transistors MA1 and MA2 are connected to the storage nodes N1 and N2, respectively. A plural of such cells are disposed in a matrix arrangement to form an SRAM.

In the present embodiment, the first differential amplifier AMP1 and the reference voltage generating circuit 2 in FIG. 1, may be composed by well known circuits respectively, detailed description thereof will be omitted.

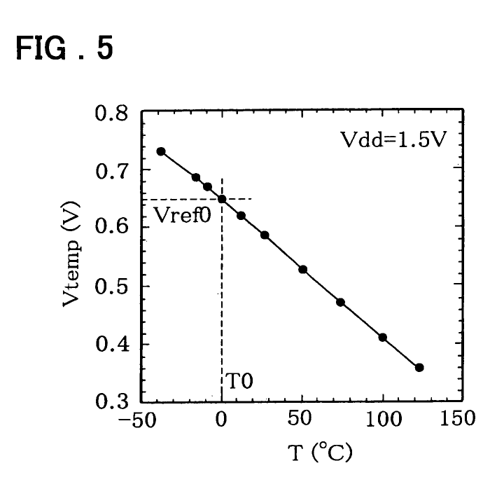

Now, operation of the semiconductor storage device according to the present embodiment will be described. The forward voltage of the diode 10 of the temperature detecting circuit 2 shown in FIG. 2 is lowered as the temperature is lowered, as a result the temperature dependency of the output voltage Vtemp is to be shown in FIG. 5. If the temperature at which the output voltage Vtemp equals to the reference voltage Vref0 is represented as T0, the potential of the output node N22 in the first differential amplifier AMP1 is at a low level due to the relation Vtemp<Vre0 in a higher temperature range (i.e., higher than T0) and is at a high level due to the relation Vtemp>Vre0 in a lower temperature range (i.e., lower than T0).

An example in which T0 is set to 0° C. is shown in FIG. 5, in which Vtemp is 0.65V. Now, operation in each case of a higher temperature range and a lower temperature range will be described separately.

In FIG. 1, the potential of the node N40 is low in the higher temperature range and hence the nMOS transistors MN50, MN60 and MN70, each gate of which is at a low level, are turned off, as a result of which, the second differential amplifier AMP2 does not operate. On the other hand, the pMOS transistor MP80, the gate of which is at a low level, is turned on, so that the variable voltage power supply Vcp of the word line driver 3 is charged with the external power supply Vdd. The voltage level of the variable voltage power supply Vcp is equal to Vdd.

The potential of the node N40 is high in the lower temperature range, and hence the pMOS transistor MP80, the gate of which is at a high level, is turned off, while the nMOS transistors NM50, MN60 and MN70 are turned on, as a result of which, the reference voltage Vref is determined by dividing the power supply voltage Vdd by the on resistances of the pMOS transistor MP50 and nMOS transistor MN50. Therefore, the value of the reference voltage Vref can be reduced by a desired voltage ΔV from the Vdd by suitably presetting the dimensions of the transistors MP50 and MN50 (channel width/gate length). Two inputs Vcp and Vref are supplied to the second differential amplifiers AMP2 which compares the two inputs (amplifies the differential input voltage). In case of Vcp<Vref, the potential of the node N62 is lowered to cause the pMOS transistor MP70 to turn on, thereby raising the Vcp.

In case of Vcp<Vref, the potential of the node N62 is raised to cause the pMOS transistor MP70 to turn off so that the Vcp is lowered by the nMOS transistor MN70. Owing to the feed back operation conducted in a manner as mentioned above, the output Vcp of the second differential amplifier AMP2 becomes equal to the reference voltage Vref. Thus, as a result, a relation is established as follows:
Vcp=Vref=Vdd−ΔV.

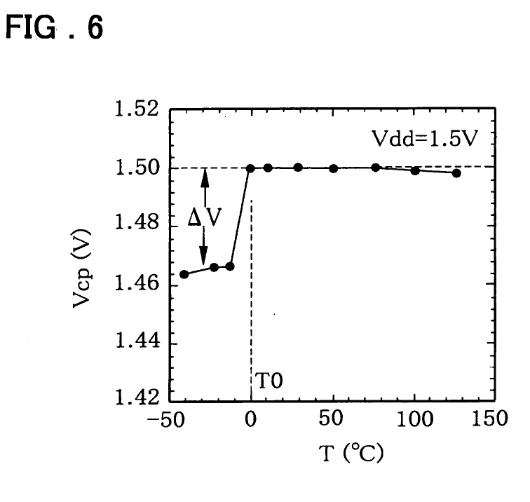

As mentioned above, as shown in FIG. 5, a relationship Vcp=Vdd is achieved in the temperature range which is higher than the temperature T0 at which Vtemp=Vref0, while a relationship Vcp=Vdd−ΔV is achieved in the temperature range which is lower than the temperature T0. It is possible to preset variable voltage power supply Vcp which is lower than Vdd by ΔV in the lower temperature range. The word line control signal IN is set to be at a low level during a data holding period, so that the potential of the word line WL is equal to that of the variable voltage power supply Vcp of the word line driver 3 as is apparent from FIG. 3. FIG. 6 shows the temperature dependency of the variable voltage power supply Vcp of the word line driver 3. In this case, the dimensions of the pMOS transistor MP50 and nMOS transistor MP50 are preset so that ΔV is about 35 mV at T0=0° C. Slight lowering of Vcp is exhibited in the higher temperature range due to the influence of the off current of nMOS transistor MN1 of the word line driver 3.

When the potential of the word line WL becomes equal to that of the variable voltage power supply Vcp, the gate potential of the access transistors MA1 and MA2 in FIG. 4 also becomes Vcp. When Vcp is lowered by ΔV than Vdd in the lower temperature range, the gate-to-source voltage becomes −ΔV and the off currents Ioffp of the access transistors MA1 and MA2 increase by a figure of ΔV/S wherein S denotes a subthreshold swing. Therefore, the above-mentioned condition (Ioffp/Ioffn)>1 can be satisfied by adjusting the dimensions of the pMOS transistor MP50 and nMOS transistor MN50 to decrease the value of ΔV even if Ioffn increases in the lower temperature range.

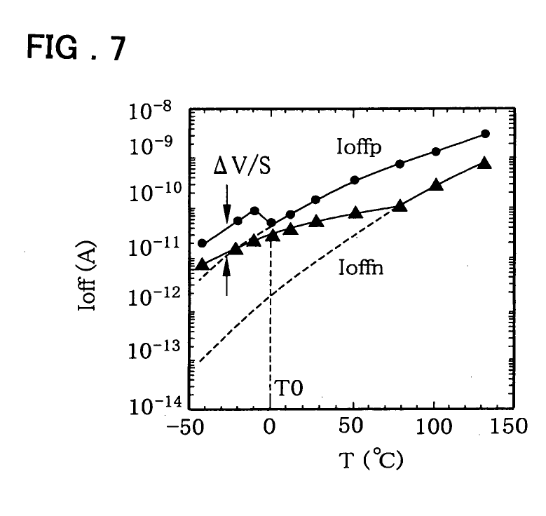

Assuming the subthreshold swing S is 83 mV/dec (Decade) at room temperature, the subthreshold swing S is 76 mV/dec at 0° C., and hence Ioffp increases by a figure of 0.46 (=2.9 times) at ΔV/S=0.46 if ΔV=35 mV. Ioffp increases by a figure of 0.92 (=8.3 times) at Δ/S=0.92 if ΔV=70 mV. The temperature dependency of Ioff at T0=0° C. and ΔV=35 mV is shown in FIG. 7. As is apparent from FIG. 7, the condition (Ioffp/Ioffn)>1 can be satisfied in a full temperature range. The larger ΔV is preset, the higher leakage level can be coped with. Practically, a trade off between the ΔV and the tolerable level of the stand-by current should be conducted.

In such a manner, the detection of the temperature T0 at which the output voltage Vtemp of the temperature detecting circuit 2 becomes equal to the output voltage Vref0 of the reference voltage generating circuit 1 is conducted in the semiconductor storage device 5. The reference voltage Vref is reduced by a voltage ΔV from the external power supply voltage Vdd in the temperature range which is not higher than the temperature T0 by means of the variable voltage generating circuit 6. Since the lowered voltage (Vdd−ΔV) is supplied to the word line WL of the memory cell 4 via the word line driver 3 as the variable voltage power supply Vcp, the storage node of the memory cell 4 can be stably held in a given level.

Therefore, data retention failure which is liable to occur in the lower temperature range, during a data-holding period can be avoided.

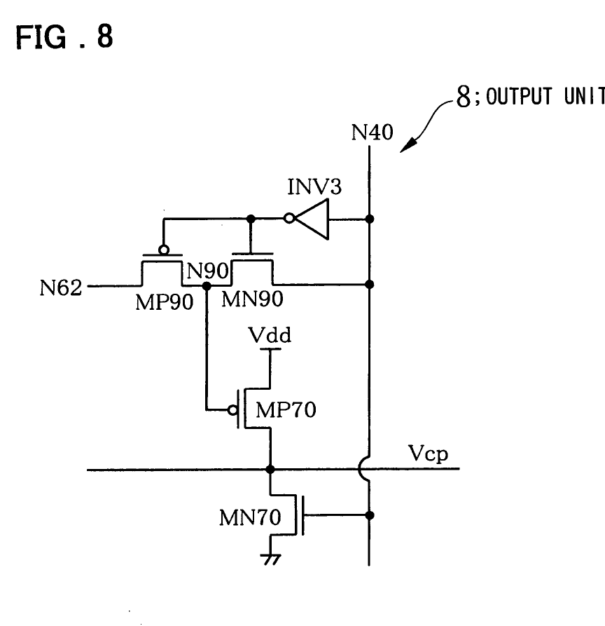

The second embodiment of the present invention will now be described with reference to FIG. 8. The configuration according to the second embodiment is mostly identical with that of the first embodiment shown in FIG. 1, except that the function of two current supplying transistors of the first embodiment is performed by a single transistor.

Referring to FIG. 8, the output unit 8 according to the present embodiment has one pMOS transistor MP70 which serves as a current supply transistor in the output unit 8. The transistor MP70 is configured so as to also perform the operation of the pMOS transistor MP80 of the first embodiment shown in FIG. 1. The gate of the transistor MP70 is connected to the node N62 of the second differential amplifier AMP2 via the pMOS transistor MP90 and to the node N40 via the nMOS transistor MN90. There is provided an inverter INV3 having its input connected to the node N40 and outputs connected to the gates of the pMOS and nMOS transistors MP90 and MN90.

The node N40 is low in the higher temperature range in the semiconductor storage device 5 and hence both the gates of pMOS and nMOS transistors MP90 and MN90 are high. Thus, the transistors MP90 and MN90 are turned off and on, respectively. Therefore, the node N90 is at a low level, so that the pMOS transistor MP70 is turned on to charge the variable voltage power supply Vcp of the word line driver 3 with the external power supply voltage Vdd.

On the other hand, the voltage on the node N40 is high in the lower temperature range and hence the gates of the pMOS and nMOS transistors MP90 and MN90 are low, so that the transistors MP90 and MN90 are turned on and off, respectively. Therefore, a feedback control is conducted so that the relationship Vcp=VddΔV is established.

In the first embodiment, two pMOS transistors MP70 and MP80 which serve as current supply transistors should have very large channel width in order to charge the variable voltage power supply Vcp of the word line driver 3 at a high speed. Accordingly, the area occupied by the transistors on a substrate increases. Although the transistors MP70 and MP80 have substantially same size, the transistors MP70 and MP80 operate only in the lower and higher temperature ranges, respectively, resulting in a low efficiency. In contrast to this, in the second embodiment, only transistor MP70 is capable of conducting the operations of the transistors MP70 and MP80 of the first embodiment to provide a high efficiency and achieve reduction in substrate occupation area.

Excepting these, the second embodiment is substantially identical with the first embodiment. In FIG. 8, components which correspond to those in FIG. 1 are represented by same reference numerals. Description thereof will be omitted herein.

In such a manner, effects which are substantially similar to those of the first embodiment can be provided by the second embodiment. In addition to this, the efficiency of the operation of the transistor is high and the substrate occupation area can be reduced.

In the foregoing, embodiments of the present invention have been described in detail. The present invention is not limited to these embodiments, various changes and modifications are possible without departing from the scope and spirit of the invention.

The semiconductor storage devices (SRAM) of the present invention are widely used mainly in the field of medium storage capacity memory.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

1. A semiconductor storage device comprising:
a plurality of four-transistor memory cells, each of said memory cells including: a pair of access transistors controlled in common by a word line; and a pair of driver transistors each connected in series with associated one of said pair of access transistors, respectively; respective connection nodes between said access transistors and said driver transistors constituting storage nodes, on which given voltage levels are held by off currents of said access transistors, during a data holding period; and
a circuit for performing control so as to increase said off currents of said access transistors, during the data holding period, in a relatively low temperature region.

2. A semiconductor storage device comprising:
a plurality of four-transistor memory cells, each of said memory cells including: a pair of access transistors controlled in common by a word line; and a pair of driver transistors, each connected in series with associated one of said pair of access transistors, respectively; respective connection nodes between said access transistors and said driver transistors constituting storage nodes, on which given voltage levels are held by off currents of said access transistors, during a data holding period;
a temperature detecting circuit for outputting a detected voltage dependent on operation temperature of said memory cells;
a reference voltage generating circuit for outputting a reference voltage independent of the operation temperature of said memory cells;
a first differential amplifier for comparing said detected voltage with said reference voltage to output a voltage of a first or second level in accordance with a result of said comparison;
a variable voltage generating circuit, receiving as two inputs a branch of the output of said first differential amplifier, for outputting an output signal, the potential of which is varied in accordance with said first and second levels of the output of said first differential amplifier; and
a word line driver, receiving the output from the variable voltage generating circuit, for supplying said word line with the output voltage of said variable voltage generating circuit.

3. The semiconductor storage device according to claim 2, wherein said variable voltage generating circuit comprises:
a reference voltage generating unit, receiving one of said branched outputs of said first differential amplifier, for generating a reference voltage;
an output unit, receiving the other one of said branched outputs of said first differential amplifier and an output of said second differential amplifier, for outputting said output signal; and
a second differential amplifier, receiving the output of said reference voltage generating unit and the output of said output unit.

4. The semiconductor storage device according to claim 3, wherein when said reference voltage is higher than said detected voltage, said first differential amplifier outputs the first level voltage and control is performed in response to the output of said first differential amplifier so as to make both said reference voltage generating unit and said second differential amplifier stop respective operations and to make said variable voltage generating circuit output a voltage which is equal to that of a power supply.

5. The semiconductor storage device according to claim 3, wherein when said reference voltage is lower than said detected voltage, said first differential amplifier outputs the second level voltage and control is performed in response to the output of said first differential amplifier so as to make both said reference voltage generating unit and said second differential amplifier start respective operations and to make said variable voltage generating circuit output a voltage which is reduced by a preset value from that of a power supply.

6. The semiconductor storage device according to claim 5, wherein said reference voltage generating unit comprises a series circuit of two transistors; and wherein
said preset value is determined by changing the dimension of each transistor of said series circuit.

7. The semiconductor storage device according to claim 2, wherein said first and second levels are low and high levels, respectively.

8. The semiconductor storage device according to claim 1, wherein said one pair of access transistors comprise pMOS transistors; and said one pair of driver transistors comprises nMOS transistors.

9. The semiconductor storage device according to claim 2, wherein said one pair of access transistors comprise pMOS transistors; and said one pair of driver transistors comprises nMOS transistors.

10. The semiconductor storage device according to claim 2, wherein said temperature detecting circuit has a temperature detecting element.

11. The semiconductor storage device according to claim 10, wherein said temperature detecting element has a diode.

12. The semiconductor storage device according to claim 11, wherein detection of temperature is conducted on the basis of a forward voltage of said diode.

13. The semiconductor storage device according to claim 2, wherein the word line driver has a power supply terminal thereof connected to the output of the variable voltage generating circuit and receives a control signal as an input to be controlled so that the potential of the word line during the data holding period is equal to that of the output from the variable voltage generating circuit.

14. The semiconductor storage device according to claim 3, wherein said output unit includes:
first and second transistors, having opposite polarities each other and connected in series between an power supply and a ground; and
a third transistor, having the same polarity as that of said first transistor, and connected between the connection node of said first and second transistors and the power supply;
wherein said first transistor has a control terminal thereof connected to the output node of the second differential amplifier;
said second third transistors have control terminals thereof connected in common to the other one of said branched outputs of said first differential amplifier; and
the connection node of said first and second transistors is connected to one of differential inputs of the second differential amplifier and is connected to a power supply terminal of the world line driver.

15. The semiconductor storage device according to claim 3, wherein said output unit includes:
first and second transistors having opposite polarities each other, and connected in series between a power supply and a ground;
third and fourth transistors having opposite polarities each other, and connected in series between the output node of the second differential amplifier and the other one of said branched outputs of the first differential amplifier; and
an inverter having an input connected to the other one of said branched outputs of said first differential amplifier and having an output connected to respective control terminals of said third and fourth transistors;
wherein said first transistor has a control terminal thereof connected to the connection node of said third and fourth transistors;
said second transistor has a control terminal thereof connected to the other one of said branched outputs of said first differential amplifier; and
the connection node of said first and second transistors is connected to one of differential inputs of the second differential amplifier and is connected to a power supply terminal of the world line driver.
